(19) United States
(12) Patent Application Publication
(10) Pub. No.: US 2016/0104702 A1
(43) Pub. Date: Apr. 14, 2016

(54) SUPER-JUNCTION TRENCH MOSFET INTEGRATED WITH EMBEDDED TRENCH SCHOTTKY RECTIFIER

(71) Applicant: Force Mos Technology Co., Ltd., New Taipei City (TW)

(72) Inventor: FU-YUAN HSIEH, New Taipei City (TW)

(73) Assignee: FORCE MOS TECHNOLOGY CO., LTD., New Taipei City (TW)

(21) Appl. No.: 14/509,526

(22) Filed: Oct. 8, 2014

(51) Int. Cl. H01L 27/06; H01L 29/423; H01L 29/872; H01L 29/417; H01L 29/10; H01L 29/49; H01L 29/78; H01L 29/06

(52) U.S. Cl. CPC H01L 27/0629; H01L 29/7827; H01L 29/7813; H01L 29/4236; H01L 29/0634; H01L 29/0696; H01L 29/41766; H01L 29/41741; H01L 29/1083; H01L 29/1095; H01L 29/4916; H01L 29/7806; H01L 29/872

(57) ABSTRACT

A super-junction trench MOSFET integrated with embedded trench Schottky rectifier is disclosed for soft reverse recovery operation. The embedded trench Schottky rectifier can be integrated in a same unit cell with the super-junction trench MOSFET.

### FIELD OF THE INVENTION

This invention relates generally to the cell structure, device configuration of power semiconductor devices. More particularly, this invention relates to a novel and improved cell structure, device configuration of a super-junction trench MOSFET (Metal Oxide Semiconductor Field Effect Transistor, the same hereinafter) integrated with embedded trench Schottky rectifier

### BACKGROUND OF THE INVENTION

Compared to the conventional trench MOSFETs, super-junction trench MOSFETs are more attractive due to its better performance. For example, FIG. 1 shows a super-junction trench MOSFET disclosed in U.S. application Ser. No. 13/568,297 (having the same inventor as the present invention), which also contains multiple trenched gates in unit cell and has advantages such as: higher breakdown voltage, lower specific Rds (drain-source resistance), minimized influence of charge imbalance, better UIS (unclamped inductive switching) capability . . . etc., especially for semiconductor devices having small size and narrow contact CD (Critical Dimension).

However, the super-junction trench MOSFET as shown in FIG. 1 also has a major drawback which is hardness of body diode reverse recovery operation, imposing large electro-magnetic interference (EMI) noise and high power dissipation.

Therefore, there is still a need in the art of the semiconductor power device, particularly for super-junction trench MOSFET design and fabrication, to provide a novel cell structure, device configuration that would resolve the problem.

### SUMMARY OF THE INVENTION

The present invention provides a novel super-junction trench MOSFET by integrating with embedded trench Schottky rectifier for soft reverse recovery operation, and provides improved device configurations by integrating trench MOSFET, super-junction diode and embedded trench Schottky rectifier together for device performance enhancement without wasting die area.

In one aspect, the present invention features a super-junction trench MOSFET integrated with embedded trench Schottky rectifier comprising a plurality of unit cells with each comprising: a substrate of a first conductivity type; an epitaxial layer of the first conductivity type onto the substrate, wherein the epitaxial layer has a lower doping concentration than the substrate; a first doped column region of the first conductivity type formed in the epitaxial layer; a pair of second doped column regions of a second conductivity type formed in the epitaxial layer, located in parallel and surrounding with the first doped column region; multiple trenched gates starting from top surface of the epitaxial layer and extending into the first doped column region; body regions of the second conductivity type extending between every two adjacent of the trenched gates and above the first and second doped column regions; source regions of the first conductivity type encompassed in the body regions and surrounding the trenched gates; a plurality of trenched source-body contacts each filled with a contact metal plug, penetrating through the source regions and the body regions and extending into the first and second doped column regions, wherein the trenched source-body contacts have a depth shallower than the trenched gates but deeper than the body regions; and at least one anti-punch through implant region formed along at least a portion of sidewalls of the trenched source-body contacts and below the source regions.

According to yet another aspect, each of the unit cells is isolated from adjacent unit cells by a dielectric layer filled in a deep trench penetrating through the epitaxial layer and downward into the substrate, wherein the second doped column regions are formed close to the deep trench. In some other preferred embodiments, the deep trench is filled with dielectric material having buried void. In yet some other preferred embodiment, each of the unit cells is not isolated from the adjacent unit cells but sharing the second doped column regions with the adjacent unit cells.

According to yet another aspect, the multiple trenched gates are each filled with a doped poly-silicon layer padded by a gate oxide layer, wherein the gate oxide layer has same thickness along sidewalls and bottom of each trenched gate. In some other preferred embodiment, the gate oxide layer has greater thickness along bottom than along sidewalls of each trenched gate.

According to yet another aspect, the present invention further comprises a doped island of the second conductivity type formed below the trenched source-body contacts and between every two adjacent gate trenches in the epitaxial layer to reduce Idsx by decreasing electric field near the embedded Schottky rectifier.

According to yet another aspect, the present invention further comprises multiple guard rings in a termination area, wherein the guard rings are formed in the epitaxial layer for breakdown voltage enhancement.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The present invention can be more fully understood by reading the following detailed description of the preferred embodiments, with reference made to the accompanying drawings, wherein:

FIG. 1 is a cross-sectional view of a super-junction trench MOSFET of prior art.

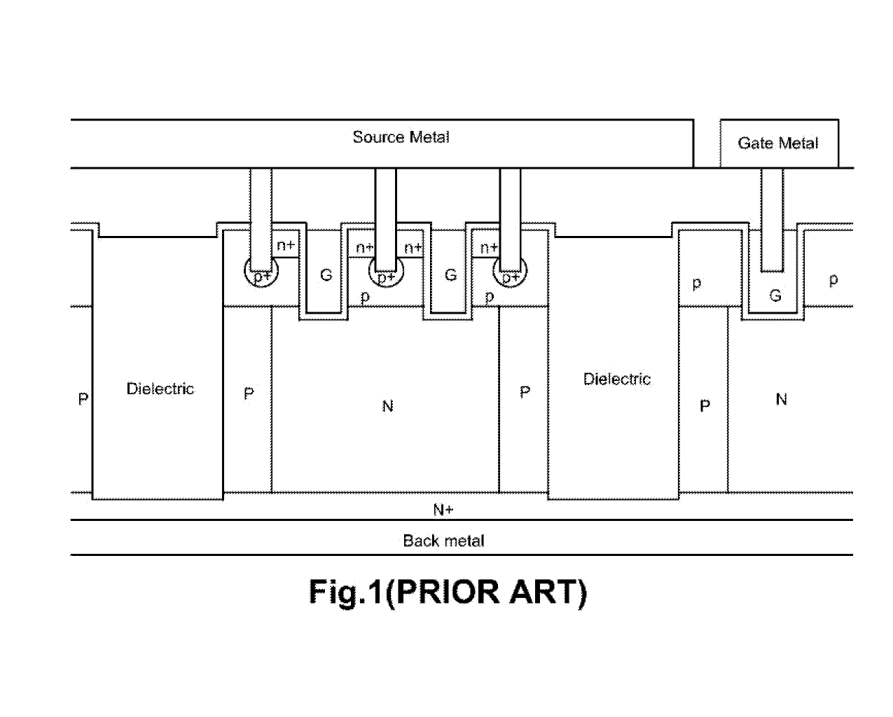

FIG. 2A is a cross-sectional view of a preferred embodiment according to the present invention.

FIG. 2B is a cross-sectional view of another preferred embodiment according to the present invention.

FIG. 2C is a cross-sectional view of another preferred embodiment according to the present invention.

FIG. 2D is a cross-sectional view of another preferred embodiment according to the present invention.

FIG. 3 is a cross-sectional view of another preferred embodiment according to the present invention.

FIG. 4 is a cross-sectional view of another preferred embodiment according to the present invention.

### DETAILED DESCRIPTION OF THE EMBODIMENTS

In the following Detailed Description, reference is made to the accompanying drawings, .which forms a part thereof, and in which is shown by way of illustration specific embodiments in which the invention may be practiced. In this regard, directional terminology, such as “top”, “bottom”, “front”, “back”, etc., is used with reference to the orientation of the Figure(s) being described. Because components of embodiments can be positioned in a number of different orientations, the directional terminology is used for purpose of illustration and is in no way limiting. It is to be understood that other embodiments may be utilized and structural or logical changes may be make without departing from the scope of the present invention. The following detailed description, therefore, is not to be taken in a limiting sense, and the scope of the present invention is defined by the appended claims. It is to be understood that the features of the various exemplary embodiments described herein may be combined with each other, unless specifically noted otherwise.

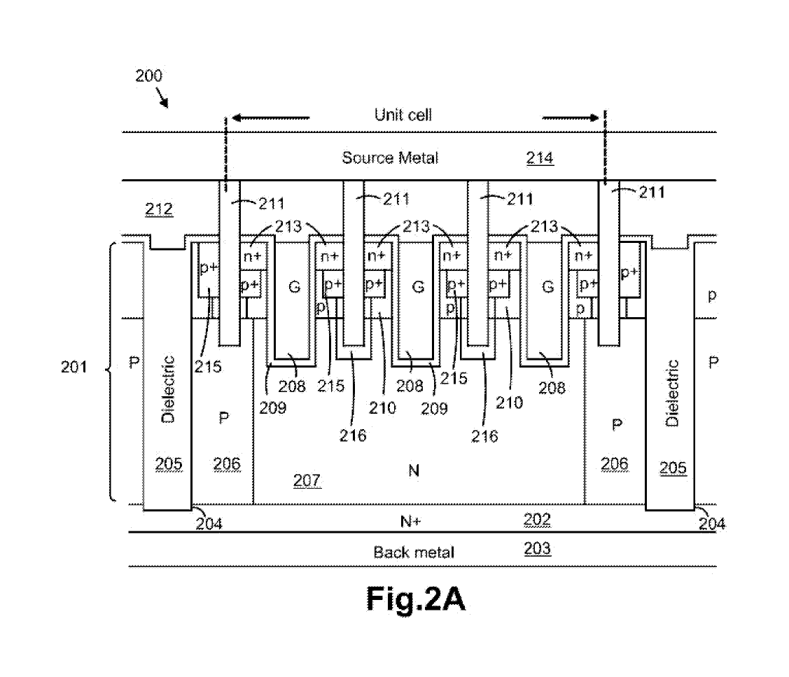

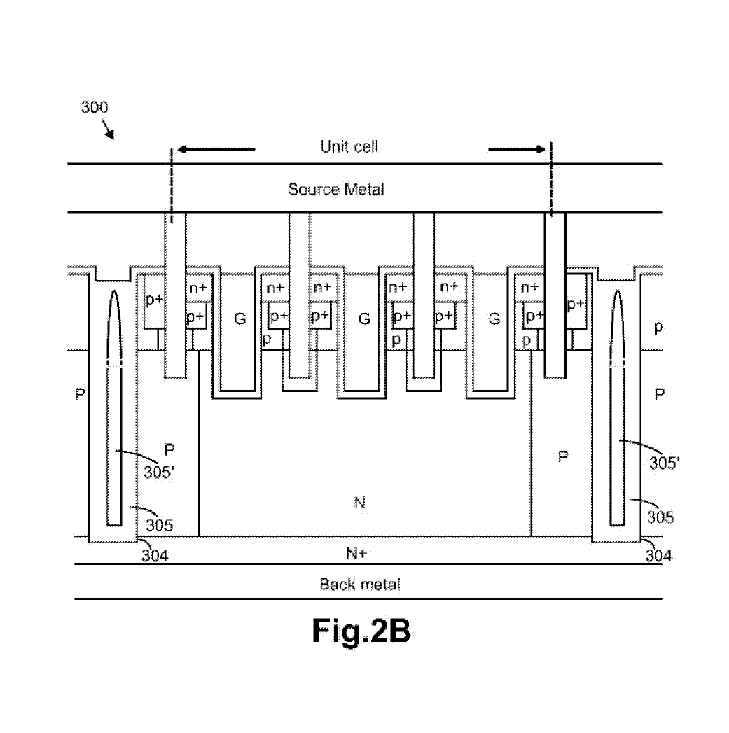

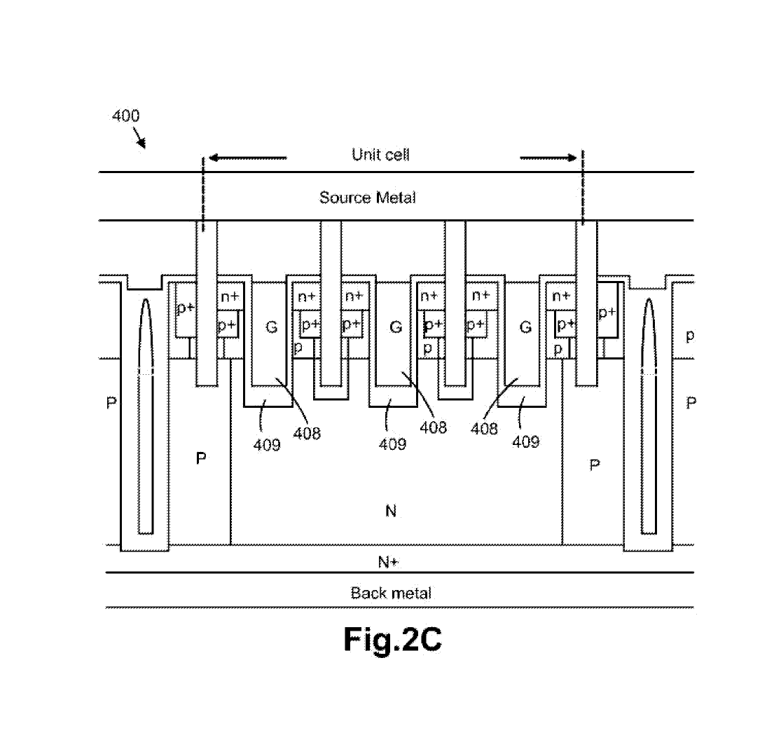

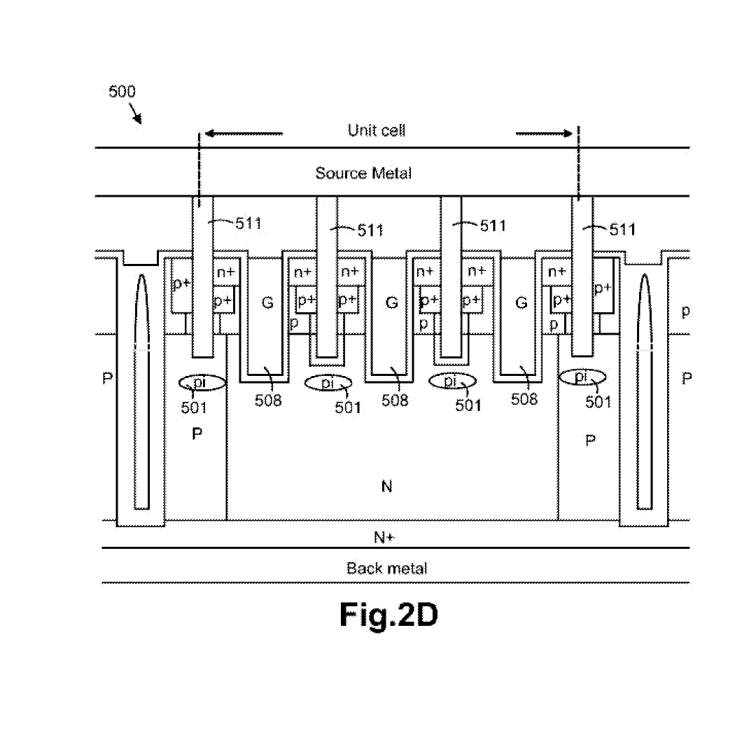

Please refer to FIG. 2A for a unit cell 200 of a preferred N-channel super-junction trench MOSFET comprising a plurality of the unit cells, wherein the unit cell 200 is formed in an N-epitaxial layer 201 supported onto an N+ substrate 202 which is coated with a back metal 203 of, for example, Ti/Ni/Ag on its rear side as a drain metal. The N-channel super-junction trench MOSFET unit cell 200 comprises a pair of deep trenches 204 filled with dielectric layer 205 and formed starting from a top surface of the N epitaxial layer 201 and vertically down extending into the N+ substrate 202. Adjacent to sidewalls of the deep trenches 204, a pair of P second doped column regions 206 are formed in parallel surrounding with an N first doped column region 207 to form the super-junction structure. The N first doped column region 207 and the P second doped column regions 206 all have column bottoms above trench bottoms of the deep trenches 204. Multiple trenched gates 208 filled with a doped poly-silicon layer (G as illustrated) padded by a gate oxide layer 209 are formed starting from the top surface of the N- epitaxial layer 201 and extending into the N first doped column region 207, wherein thickness of gate oxide layer 209 along bottom of the trenched gates 208 is equal to or thinner than that along sidewalls of the trenched gates 208. Meanwhile, p body regions 210 above the N first doped column region 207 and the P second doped column regions 206 are extending between every two adjacent of the trenched gates 208. A plurality of trenched source-body contacts 211 each filled with a contact metal plug are penetrating through a contact interlayer 212, n+ source regions 213, the p body regions 210 and further extending into the N first doped column region 207 and the P second doped column regions 206, respectively, wherein the n+source regions 213 are located between sidewalls of the trenched source-body contacts 211 and the trenched gates 208, and the trenched source-body contacts 211 have a depth shallower than the gate trenches 208 but deeper than the p body regions 210. As the lower portion of the trenched source-body contacts 211 and the interfaced N first doped column region 207 together form the embedded trench Schottky rectifiers, the embedded trench Schottky rectifiers formed below the p body regions 210 along trench sidewalls and bottom of lower portion of trenched source-body contacts 211 have a depth shallower than the adjacent trenched gates 208, thus avoiding the high leakage current and enhancing pinch-off effect compared. According to this embodiment, the contact metal plug 211 can be implemented by a tungsten metal layer padded by a barrier metal layer of Ti/TiN or Co/TiN or Ta/TiN; the contact interlayer 212 can be implemented by being composed of a Phosphorus Silicate Glass (PSG the same hereinafter) or Boron Phosphorus Silicate Glass (BPSG the same hereinafter) layer; and the trenched source-body contacts connect the n+source regions 213 and the p body regions 210 to a source metal 214 comprising Al alloys or Cu padded by a resistance-reduction layer of Ti or TiN (not shown). A first p+ anti-punch through implant region 215 is formed along a higher portion of sidewalls of the trenched source-body contacts 211 and below the n+ source regions 213 to achieve pronounced anti-punch through effects and also to reduce body contact resistance, wherein the first p+ anti-punch through implant region 215 has a higher doping concentration than the P body regions 210. A second anti-punch through implant region 216 is formed underneath the first p+anti-punch through implant region 215, surrounding bottom and a lower portion of the sidewalls of each of the trenched source-body contacts 211 extending into the N first doped column region 207. What should be noticed is that, the part of the second anti-punch through implant region 216 located in the p body regions 210 is P type and having a higher doping concentration than the p body regions 210; the other part of the second anti-punch through implant region 216 underneath the p body regions 210 has either n- or p-doping type depending on the second anti-punch through implant dose.

FIG. 2B shows a cross-section view of another preferred unit cell 300 of an N-channel super-junction trench MOSFET, which is similar to the unit cell 200 in FIG. 2A except that, a void 305′ is existed in the doped poly-silicon layer 305 filled in each of the deep trenches 304.

FIG. 2C shows a cross-section view of another preferred unit cell 400 of an N-channel super-junction trench MOSFET, which is similar to the unit cell 300 in FIG. 2B except that, the gate oxide layer 409 has a greater thickness along bottom than along sidewalls of the trenched gates 408.

FIG. 2D shows a cross-sectional view of another preferred unit cell 500 of an N-channel super-junction trench MOSFET which is similar to the unit cell 300 in FIG. 2B except that, the unit cell 500 further comprises at least a P island (pi, as illustrated in FIG. 2D) 501 below each of the trenched source-body contacts 511 and between every two adjacent gate trenches 508 to reduce Idsx by decreasing electric field near schottky rectifier area.

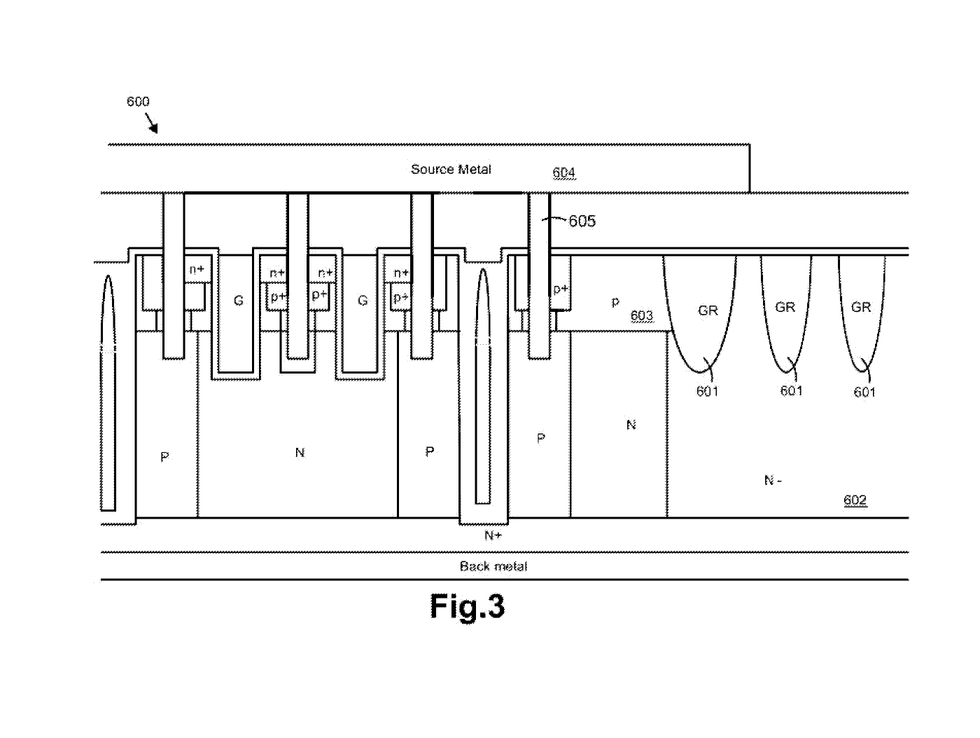

FIG. 3 shows a cross-section view of another preferred unit cell 600 of an N-channel super-junction trench MOSFET, which is similar to the unit cell 300 in FIG. 2B except that, a termination area is formed adjacent to the unit cell 600, which comprises multiple guard rings 601 (GR, as illustrated) extending into the N-epitaxial layer 602 to maintain breakdown voltage. Besides, the p body region 603 adjacent to the guard rings 601 is shorted to the source metal 604 by a trenched body contact 605 filled with the contact metal plug.

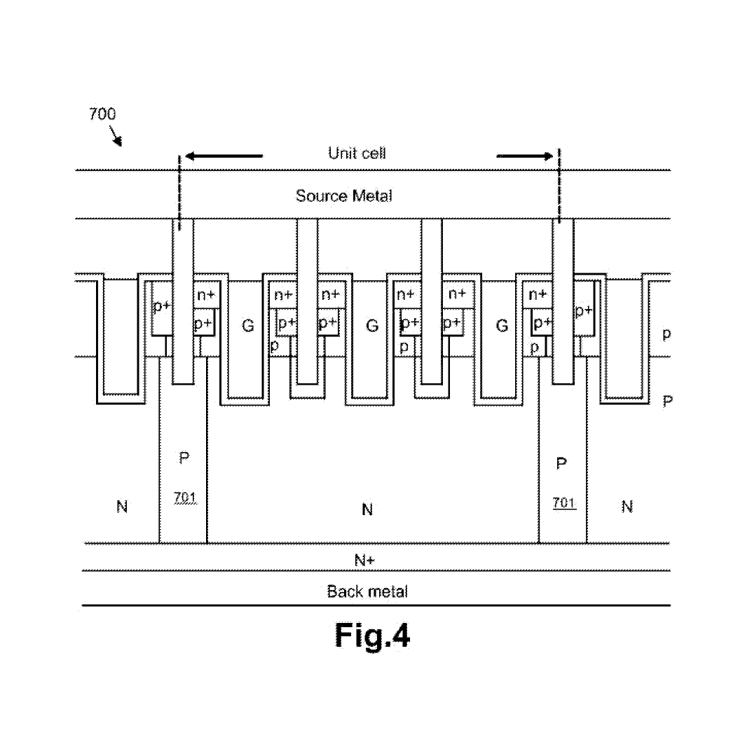

FIG. 4 shows a cross-section view of another preferred unit cell 700 of an N-channel super-junction trench MOSFET, which is similar to the unit cell 200 in FIG. 2A except that, the unit cell 700 is not isolated from adjacent unit cells by dielectric layer but sharing the same P second doped column regions 701 with the adjacent unit cells. The super-junction structure in this embodiment can be implemented by using a process of alternate Boron implantation and N epitaxial growth for several turns, or by forming deep trenches into the N epitaxial layer and refilling the deep trenches with P type epitaxial layer.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A super-junction trench MOSFET integrated with embedded trench Schottky rectifier comprising a plurality of unit cells with each unit cell comprising:
a substrate of a first conductivity type;
an epitaxial layer of said first conductivity type grown on said substrate, said epitaxial layer having a lower doping concentration than said substrate;
a first doped column region of said first conductivity type formed in said epitaxial layer;
a pair of second doped column regions of a second conductivity type formed in said epitaxial layer, located in parallel and surrounding with said first doped column region;
multiple trenched gates starting from top surface of said epitaxial layer and extending into said first doped column region, refilled with a doped poly-silicon layer padded by a gate oxide layer;
body regions of said second conductivity type extending between every two adjacent of said trenched gates and above said first and said second doped column regions;
source regions of said first conductivity type encompassed in said body regions and surrounding said trenched gates;
a plurality of trenched source-body contacts each filled with a contact metal plug, penetrating through said source regions and said body regions and extending into said first and second doped column regions, wherein said trenched source-body contacts have a depth shallower than said trenched gates but deeper than said body regions; and
at least one anti-punch through implant region formed along at least a portion of sidewalls of said trenched source-body contacts and below said source regions.

2. The super-junction trench MOSFET of claim 1, wherein said at least one anti-punch through implant region comprises a first anti-punch through implant region of said second conductivity type along an upper portion of sidewalls of said trenched source-body contacts below said source regions, wherein said first anti-punch through implant region has a higher doping concentration than said body regions.

3. The super-junction trench MOSFET of claim 1, wherein said at least one anti-punch through implant region comprises: a first anti-punch through implant region of said second conductivity type along an upper portion of sidewalls of said trenched source-body contacts below said source regions, wherein said first anti-punch through implant region has a higher doping concentration than said body regions; and a second anti-punch through implant region surrounding bottoms and a lower portion of sidewalls of said trenched source-body contacts below said first anti-punch through implant region, wherein said second anti-punch through implant region has either said first or said second conductivity doping type.

4. The super-junction trench MOSFET of claim 1 further comprising at least a doped island region of said second conductivity type formed below the bottoms of said trenched source-body contacts and between every two adjacent gate trenches.

5. The super-junction trench MOSFET of claim 1 further comprising a deep trench penetrating through said epitaxial layer and downward into said substrate, refilled with dielectric layer to isolate said unit cells from each other, wherein said second doped column regions are formed close to said deep trench.

6. The super-junction trench MOSFET of claim 1, wherein said unit cell is sharing said second doped column regions with adjacent unit cells.

7. The super-junction trench MOSFET of claim 1 further comprising multiple guard rings in a termination area.

8. The super-junction trench MOSFET of claim 1, wherein said gate oxide layer has a greater thickness along bottom than along sidewalls of said trenched gates.

9. The super-junction trench MOSFET of claim 1, wherein thickness of said gate oxide layer on bottom of said trenched gates is equal to or thinner than that along sidewalls of said trenched gates.

10. The super-junction trench MOSFET of claim 1 further comprising a void existed in said doped poly-silicon layer filled into each of said trenched gates.
